(19) United States
(12) Patent Application Publication
(10) Pub. No.: US 2024/0322027 A1
(43) Pub. Date: Sep. 26, 2024

(54) SEMICONDUCTOR DEVICE AND METHOD FOR MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Hitoshi KOBAYASHI, Yamato Kanagawa (JP); Masaaki ONOMURA, Setagaya Tokyo (JP); Toru SUGIYAMA, Musashino Tokyo (JP); Akira YOSHIOKA, Yokohama Kanagawa (JP); Yasuhiro ISOBE, Narashino Chiba (JP); Tetsuya OHNO, Yokohama Kanagawa (JP); Hideki SEKIGUCHI, Yokohama Kanagawa (JP); Hung HUNG, Kawasaki Kanagawa (JP); Yorito KAKIUCHI, Yokohama Kanagawa (JP)

(21) Appl. No.: 18/454,444

(22) Filed: Aug. 23, 2023

(30) Foreign Application Priority Data
Mar. 22, 2023 (JP) 2023-045980

(51) Int. Cl. H01L 29/778; H01L 29/20; H01L 29/417; H01L 29/66

(52) U.S. Cl. CPC H01L 29/7786; H01L 29/2003; H01L 29/41725; H01L 29/66462

(57) ABSTRACT

A conductor layer is positioned between a gate electrode and a drain electrode. The conductor layer contacts a nitride semiconductor layer. The conductor layer is electrically connected with the drain electrode. The drain electrode includes a first part contacting the nitride semiconductor layer, and a second part positioned further toward the conductor layer side than the first part in a first direction. An insulating film includes a portion positioned between the conductor layer and the drain electrode. The second part is located on the portion of the insulating film.

### CROSS-REFERENCE TO RELATED APPLICATION

This application is based upon and claims the benefit of priority from Japanese Patent Application No. 2023-045980, filed on Mar. 22, 2023; the entire contents of which are incorporated herein by reference.

### FIELD

Embodiments described herein relate generally to a semiconductor device and a method for manufacturing a semiconductor device.

### BACKGROUND

HEMTs (High Electron Mobility Transistors) that use a gallium nitride material are known as power devices. Problems of such devices include a current collapse phenomenon in which the on-resistance increases when the device is operated at a high voltage.

### BRIEF DESCRIPTION OF THE DRAWINGS

FIG. 1 is a schematic plan view of a semiconductor device of a first embodiment;

FIG. 2 is an A-A cross-sectional view of FIG. 1;

FIG. 3 is a schematic cross-sectional view of a semiconductor device of a second embodiment;

FIG. 4 is a schematic cross-sectional view of a semiconductor device of a third embodiment;

FIG. 5 to FIG. 10 are schematic cross-sectional views showing a method for manufacturing the semiconductor device of the first embodiment;

FIG. 11 to FIG. 14 are schematic cross-sectional views showing a method for manufacturing the semiconductor device according to a first example of the third embodiment;

FIG. 15 and FIG. 16 are schematic cross-sectional views showing a method for manufacturing the semiconductor device according to a second example of the third embodiment; and

FIG. 17 to FIG. 20 are schematic cross-sectional views showing a method for manufacturing the semiconductor device according to a third example of the third embodiment.

### DETAILED DESCRIPTION

According to one embodiment, a semiconductor device includes a nitride semiconductor layer including a first layer, and a second layer located on the first layer, the second layer having a wider bandgap than the first layer; a source electrode located on the nitride semiconductor layer, the source electrode contacting the nitride semiconductor layer; a drain electrode located on the nitride semiconductor layer, the drain electrode being positioned distant to the source electrode in a first direction, the drain electrode contacting the nitride semiconductor layer; a gate electrode positioned between the source electrode and the drain electrode, the gate electrode not contacting the nitride semiconductor layer; an insulating film located on the nitride semiconductor layer between the source electrode and the drain electrode; and a conductor layer positioned between the gate electrode and the drain electrode, the conductor layer contacting the nitride semiconductor layer, the conductor layer being electrically connected with the drain electrode, the drain electrode including a first part contacting the nitride semiconductor layer, and a second part positioned further toward the conductor layer side than the first part in the first direction, the insulating film including a portion positioned between the conductor layer and the drain electrode, the second part being located on the portion of the insulating film.

Exemplary embodiments will now be described with reference to the drawings. Similar components in the drawings are marked with like reference numerals.

### First Embodiment

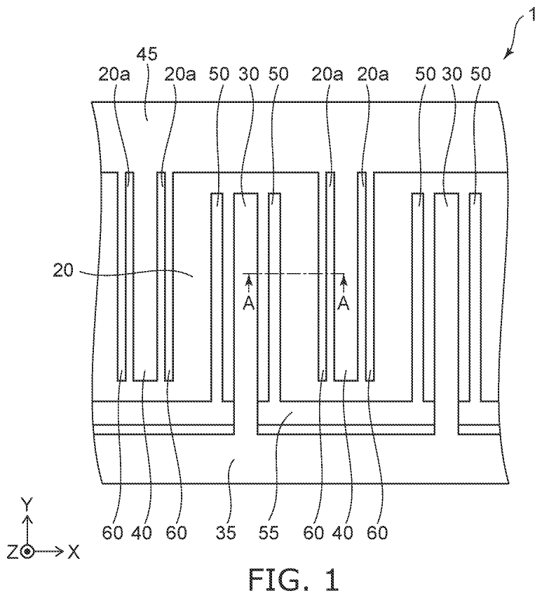

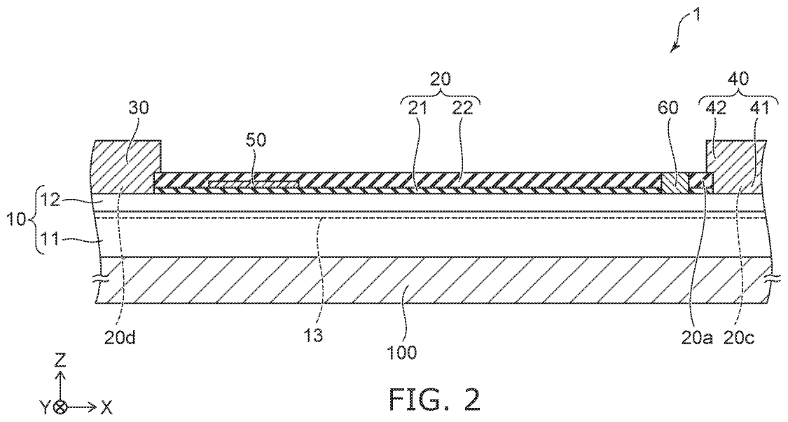

FIG. 1 is a schematic plan view of a semiconductor device 1 of a first embodiment. FIG. 2 is an A-A cross-sectional view of FIG. 1. Two directions orthogonal to each other in the drawings are taken as a first direction X and a second direction Y. A direction orthogonal to the first and second directions X and Y is taken as a third direction Z. In the specification, the thickness direction is along the third direction Z.

As shown in FIG. 2, the semiconductor device 1 of the first embodiment includes a nitride semiconductor layer 10. The nitride semiconductor layer 10 includes a first layer 11 and a second layer 12. The second layer 12 is located on the first layer 11 in the third direction Z. The bandgap of the second layer 12 is greater than the bandgap of the first layer 11. For example, the first layer 11 is a GaN layer; and the second layer 12 is an AlGaN layer. A two-dimensional electron gas 13 is distributed in the first layer 11 at the vicinity of the interface with the second layer 12. The thickness of the nitride semiconductor layer 10 is, for example, 5 μm. The thickness of the second layer 12 is less than the thickness of the first layer 11, e.g., 30 nm.

The semiconductor device 1 can further include a substrate 100 supporting the nitride semiconductor layer 10. For example, a silicon substrate can be used as the substrate 100.

The semiconductor device 1 includes a source electrode 30 located on the nitride semiconductor layer 10, and a drain electrode 40 that is located on the nitride semiconductor layer 10 and positioned distant to the source electrode 30 in the first direction X. The source electrode 30 and the drain electrode 40 can include, for example, at least one of Ti, Al, or TiN.

The source electrode 30 contacts the nitride semiconductor layer 10. The source electrode 30 has an ohmic contact with the nitride semiconductor layer 10. In the example shown in FIG. 2, the source electrode 30 contacts the second layer 12.

The semiconductor device 1 further includes a gate electrode 50. The gate electrode 50 is positioned between the source electrode 30 and the drain electrode 40 in the first direction X. For example, the gate electrode 50 can include TiN. The thickness of the gate electrode 50 is, for example, 50 nm. The distance (the shortest distance) in the first direction X between the drain electrode 40 and the gate electrode 50 is greater than the distance (the shortest distance) in the first direction X between the source electrode 30 and the gate electrode 50.

The semiconductor device 1 further includes an insulating film 20 located on the nitride semiconductor layer 10 between the source electrode 30 and the drain electrode 40. The insulating film 20 includes a first film 21 located at a surface of the nitride semiconductor layer 10, and a second film 22 located on the first film 21. The first film 21 is located between the gate electrode 50 and the nitride semiconductor layer 10; and the gate electrode 50 does not contact the nitride semiconductor layer 10. The second film 22 covers the gate electrode 50. For example, silicon nitride films can be used as the first and second films 21 and 22. The thickness of the first film 21 is less than the thickness of the second film 22 and is, for example, not less than 20 nm and not more than 40 nm. The thickness of the second film 22 is, for example, not less than 100 nm and not more than 200 nm.

The semiconductor device 1 further includes a conductor layer 60. The conductor layer 60 is positioned between the gate electrode 50 and the drain electrode 40 in the first direction X. The conductor layer 60 contacts the nitride semiconductor layer 10. In the example shown in FIG. 2, the conductor layer 60 contacts the surface of the second layer 12. The lower surface of the conductor layer 60 may be position partway through the second layer 12 in the thickness direction. The conductor layer 60 may not reach the two-dimensional electron gas 13. The conductor layer 60 may or may not have an ohmic contact with the nitride semiconductor layer 10. For example, tungsten, polycrystalline silicon doped with an impurity, etc., can be used as the material of the conductor layer 60.

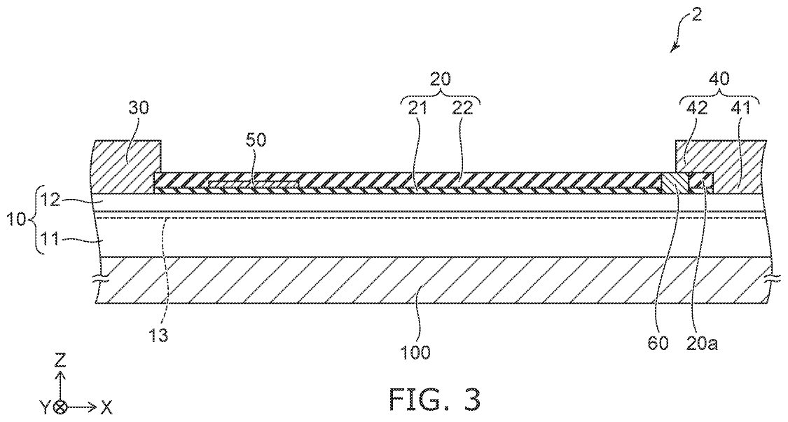

FIG. 2 illustrates a cross section of one cell of the semiconductor device 1. One cell has the configuration described above. In the semiconductor device 1, multiple cells are repeated in the first direction X. FIG. 3 and subsequent cross-sectional views also illustrate the cross section of one cell.

The conductor layer 60 is electrically connected with the drain electrode 40. According to the first embodiment, the conductor layer 60 is electrically connected with the drain electrode 40 via a drain wiring part 45 shown in FIG. 1.

As shown in FIG. 1, the semiconductor device 1 can include the drain wiring part 45 extending in the first direction X. The multiple drain electrodes 40 and the multiple conductor layers 60 are connected with the drain wiring part 45 and extend in the second direction Y from the drain wiring part 45. Each drain electrode 40 is positioned between two conductor layers 60 in the first direction X.

The semiconductor device 1 can further include a source wiring part 35 extending in the first direction X, and a gate wiring part 55 extending in the first direction X. The source wiring part 35 is positioned distant to the drain wiring part 45 in the second direction Y. The gate wiring part 55 is positioned between the drain wiring part 45 and the source wiring part 35 in the second direction Y.

The multiple source electrodes 30 are connected with the source wiring part 35 and extend in the second direction Y from the source wiring part 35 toward the drain wiring part 45. The multiple gate electrodes 50 are connected with the gate wiring part 55 and extend in the second direction Y from the gate wiring part 55 toward the drain wiring part 45. Each source electrode 30 is positioned between two gate electrodes 50 in the first direction X.

An external circuit applies a drain potential to the multiple drain electrodes 40 and the multiple conductor layers 60 via the drain wiring part 45, applies a source potential to the multiple source electrodes 30 via the source wiring part 35, and applies a gate potential to the multiple gate electrodes 50 via the gate wiring part 55. When the semiconductor device 1 operates, the drain potential is greater than the source potential.

As shown in FIG. 2, the drain electrode 40 includes a first part 41 and a second part 42. The first part 41 and the second part 42 are provided as a continuous body of the same material. The first part 41 contacts the nitride semiconductor layer 10. In the example, the first part 41 contacts the second layer 12. The second part 42 is positioned further toward the conductor layer 60 side than the first part 41 in the first direction X.

The insulating film 20 includes a portion 20a positioned between the conductor layer 60 and the drain electrode 40 in the first direction X. The second part 42 of the drain electrode 40 is located on the portion 20a of the insulating film 20. The portion 20a of the insulating film 20 is located between the nitride semiconductor layer 10 and the second part 42 of the drain electrode 40.

The distance (the shortest distance) between the conductor layer 60 and the first part 41 in the first direction X is less than the distance (the shortest distance) between the gate electrode 50 and the conductor layer 60 in the first direction X. In other words, the conductor layer 60 is located at a position more proximate to the drain electrode 40 than the gate electrode 50 in the first direction X.

In a general process, it is easy for a portion (the second part 42) of the drain electrode 40 to extend onto the insulating film 20 when being formed. In such a case, when a high voltage is applied between the drain electrode 40 and the source electrode 30, an electric field easily concentrates at the portion 20a of the insulating film 20 on which the drain electrode 40 extends, and electrons from the nitride semiconductor layer 10 move more easily to the insulating film 20 and become trapped in the insulating film 20. The electrons that are trapped in the insulating film 20 easily deplete the two-dimensional electron gas 13 under the insulating film 20, causing a current collapse phenomenon in which the on-resistance increases over time.

According to the embodiment, the conductor layer 60 is electrically connected with the drain electrode 40 and is located proximate to the drain electrode 40 so that the portion 20a of the insulating film 20 is interposed between the drain electrode 40. Therefore, the electric field does not easily concentrate at the portion 20a of the insulating film 20 even when a high voltage is applied between the drain electrode 40 and the source electrode 30, the electrons that are trapped in the portion 20a of the insulating film 20 can be reduced, and the current collapse phenomenon can be suppressed.

### Second Embodiment

FIG. 3 is a schematic cross-sectional view of a semiconductor device 2 of a second embodiment.

In the semiconductor device 2 of the second embodiment, the conductor layer 60 is electrically connected with the drain electrode 40 because the second part 42 of the drain electrode 40 contacts the conductor layer 60. The second part 42 extends from the first part 41 over the upper surface of the portion 20a of the insulating film 20 toward the conductor layer 60 and contacts at least a portion of the upper surface of the conductor layer 60. Therefore, the electric field does not easily concentrate at the portion 20a of the insulating film 20 even when a high voltage is applied between the drain electrode 40 and the source electrode 30, the electrons that are trapped in the portion 20a of the insulating film 20 can be reduced, and the current collapse phenomenon can be suppressed.

### Third Embodiment

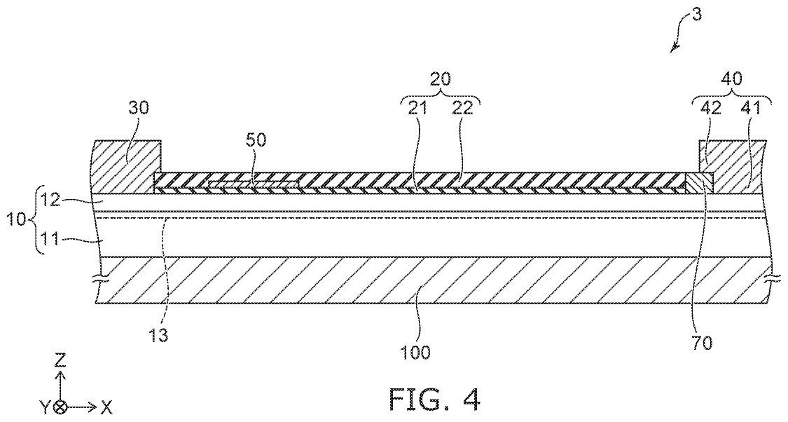

FIG. 4 is a schematic cross-sectional view of a semiconductor device 3 of a third embodiment.

The semiconductor device 3 includes a conductive part 70 positioned between the insulating film 20 and the drain electrode 40 in the first direction X. The conductive part 70 contacts the nitride semiconductor layer 10. In the example shown in FIG. 4, the conductive part 70 contacts the surface of the second layer 12. The lower surface of the conductive part 70 may be positioned partway through the second layer 12 in the thickness direction. The conductive part 70 may not reach the two-dimensional electron gas 13. The conductive part 70 may or may not have an ohmic contact with the nitride semiconductor layer 10. The conductive part 70 contacts the drain electrode 40 and is electrically connected with the drain electrode 40.

The insulating film 20 is not located between the conductive part 70 and the drain electrode 40. The drain electrode 40 is not positioned to extend onto the insulating film 20. The second part 42 of the drain electrode 40 is provided to extend onto the conductive part 70 rather than the insulating film 20. Therefore, even when a high voltage is applied between the drain electrode 40 and the source electrode 30, the electrons in the conductive part 70 flow to the drain electrode 40 and do not accumulate easily in the conductive part 70. The current collapse phenomenon can be suppressed thereby.

As described below, the conductive part 70 can be formed by a process other than the process of forming the drain electrode 40. For example, the conductive part 70 is made of a material that has a different composition from the drain electrode 40.

For example, the same material as the conductor layer 60 described above can be used as the material of the conductive part 70. Also, the conductive part 70 can be formed by diffusing a metal into a portion of the insulating film 20. The conductive part 70 also can be formed by causing crystal defects in a portion of the insulating film 20 by ion implantation. Also, a semi-insulating film that has a higher conductivity than the insulating film 20 can be used as the conductive part 70.

### Method for Manufacturing Semiconductor Device

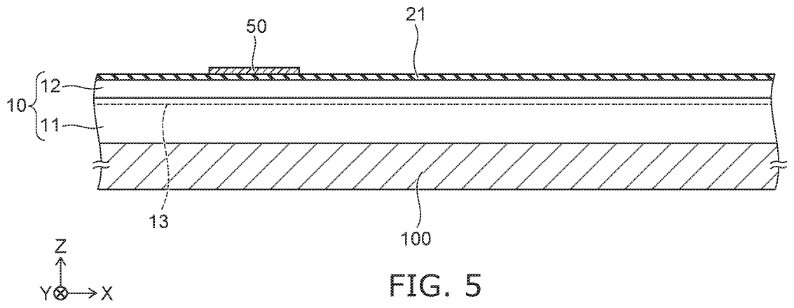

A method for manufacturing the semiconductor device of the first embodiment will now be described with reference to FIGS. 5 to 10.

As shown in FIG. 5, the method for manufacturing the semiconductor device of the first embodiment includes a process of preparing the nitride semiconductor layer 10. For example, the nitride semiconductor layer 10 can be formed on the substrate 100 by MOCVD (metal organic chemical vapor deposition).

The method for manufacturing the semiconductor device of the first embodiment includes a process of forming the insulating film 20 on the nitride semiconductor layer 10. The process of forming the insulating film 20 includes a process of forming the first film 21 on the nitride semiconductor layer 10. For example, a silicon nitride film can be formed as the first film 21 by CVD (Chemical Vapor Deposition).

The method for manufacturing the semiconductor device of the first embodiment includes a process of forming the gate electrode 50 on the first film 21. For example, a TiN film can be formed as the gate electrode 50 by sputtering.

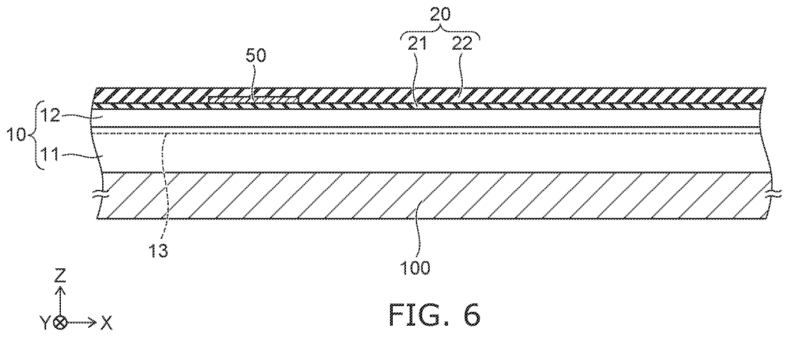

As shown in FIG. 6, the process of forming the insulating film 20 includes a process of forming the second film 22 on the first film 21 to cover the gate electrode 50. For example, a silicon nitride film can be formed as the second film 22 by CVD.

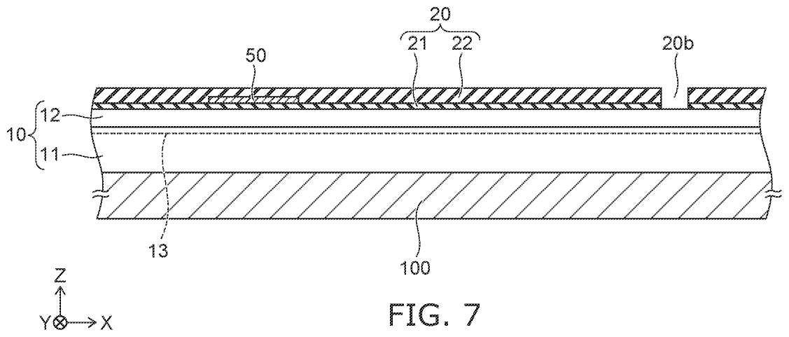

As shown in FIG. 7, the method for manufacturing the semiconductor device of the first embodiment includes a process of forming a first opening 20b in the insulating film 20 to expose the nitride semiconductor layer 10. For example, the first opening 20b can be formed by RIE (Reactive Ion Etching).

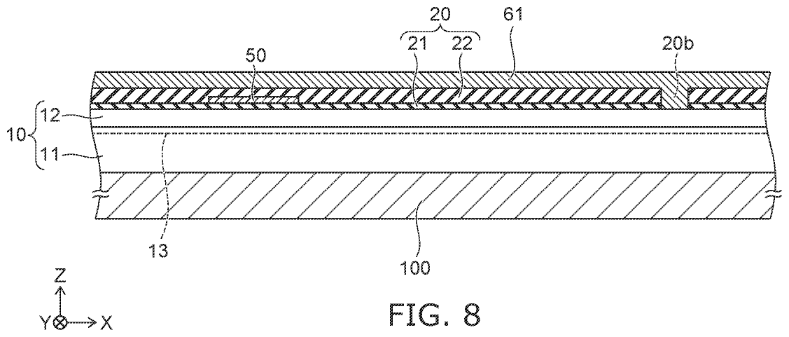

The method for manufacturing the semiconductor device of the first embodiment includes a process of forming the conductor layer 60 in the first opening 20b. As shown in FIG. 8, the process of forming the conductor layer 60 includes a process of forming a conductive film 61 on the insulating film 20 and in the first opening 20b. For example, a tungsten film or a polycrystalline silicon film doped with an impurity can be formed as the conductive film 61 by CVD.

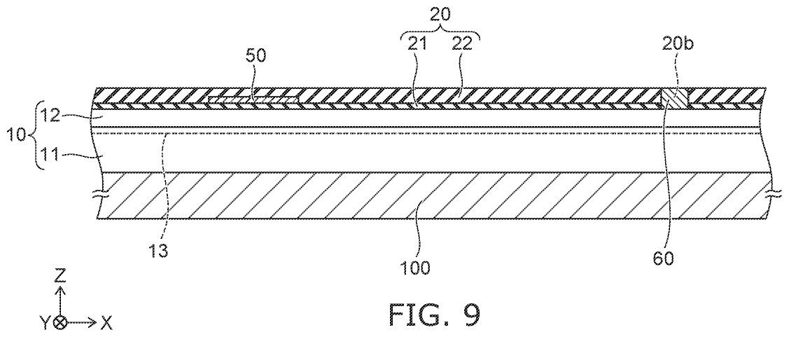

The process of forming the conductor layer 60 includes a process of removing the conductive film 61 on the insulating film 20 by, for example, CMP (Chemical Mechanical Polishing) or etch-back. Accordingly, the conductor layer 60 is formed in the first opening 20b of the insulating film 20 as shown in FIG. 9.

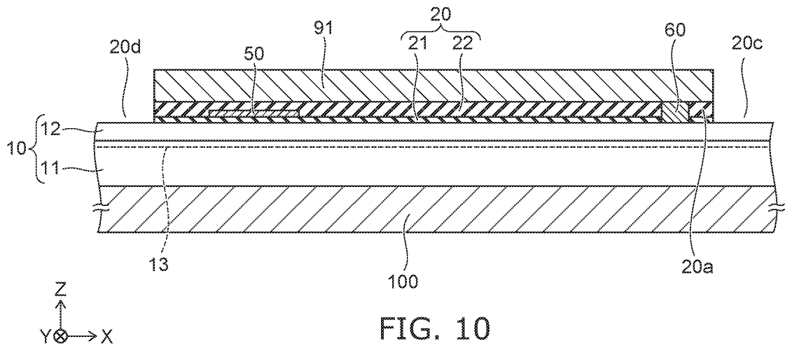

As shown in FIG. 10, the method for manufacturing the semiconductor device of the first embodiment includes a process of forming a second opening 20c in the insulating film 20. A third opening 20d can be formed in the insulating film 20 simultaneously with the second opening 20c. For example, the second opening 20c and the third opening 20d can be formed by RIE using a mask 91. For example, a resist mask can be used as the mask 91.

The nitride semiconductor layer 10 is exposed from under the insulating film 20 in the second and third openings 20c and 20d. The second opening 20c is formed so that the portion 20a of the insulating film 20 remains between the conductor layer 60 and the second opening 20c. The portion 20a of the insulating film 20 is positioned between the conductor layer 60 and the second opening 20c in the first direction X.

The mask 91 is removed after the second and third openings 20c and 20d are formed. The method for manufacturing the semiconductor device of the first embodiment includes a process of forming the drain electrode 40 after the mask 91 is removed.

As shown in FIG. 2, the drain electrode 40 includes the first part 41 that contacts the nitride semiconductor layer 10 in the second opening 20c, and the second part 42 that is positioned on the portion 20a of the insulating film 20 and is positioned further toward the conductor layer 60 side than the first part 41.

The source electrode 30 can be formed simultaneously with the drain electrode 40. For example, the drain electrode 40 and the source electrode 30 can be formed by sputtering. The source electrode 30 contacts the nitride semiconductor layer 10 in the third opening 20d. A portion of the source electrode 30 is positioned on the insulating film 20.

By causing the second part 42 to contact the upper surface of the conductor layer 60 in the process of forming the drain electrode 40, the semiconductor device 2 of the second embodiment shown in FIG. 3 is obtained.

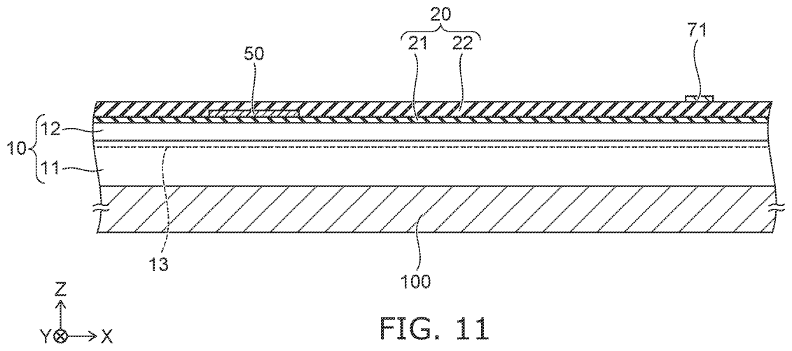

A method for manufacturing a semiconductor device according to a first example of the third embodiment will now be described with reference to FIGS. 11 to 14. According to the manufacturing method in FIG. 11 and subsequent drawings, the nitride semiconductor layer 10, the insulating film 20, the gate electrode 50, and the source electrode 30 are formed similarly to those of the first embodiment described above; and a description may be omitted.

According to the method for manufacturing the semiconductor device according to the first example of the third embodiment, the processes up to the process of forming the insulating film 20 shown in FIG. 6 above are similar to the first embodiment.

Subsequently, the method for manufacturing the semiconductor device according to the first example of the third embodiment includes a process of forming a metal film 71 on the insulating film 20 as shown in FIG. 11. The metal film 71 can include, for example, at least one of Ti or Al. For example, the metal film 71 can be formed by sputtering.

The method for manufacturing the semiconductor device according to the first example of the third embodiment includes a process of thermally diffusing, into the insulating film 20 under the metal film 71, the metal included in the metal film 71. For example, the metal included in the metal film 71 is thermally diffused by RTA (Rapid Thermal Anneal). At this time, the heating temperature can be, for example, not less than 500° C. and not more than 1200° C.

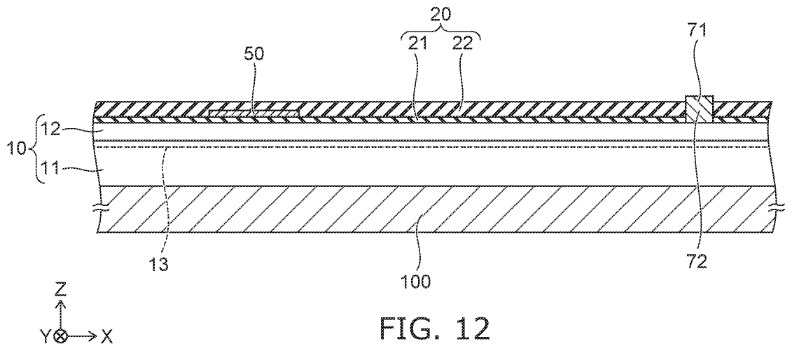

As shown in FIG. 12, a metal diffusion region 72 is formed in the insulating film 20 by the thermal diffusion of the metal included in the metal film 71.

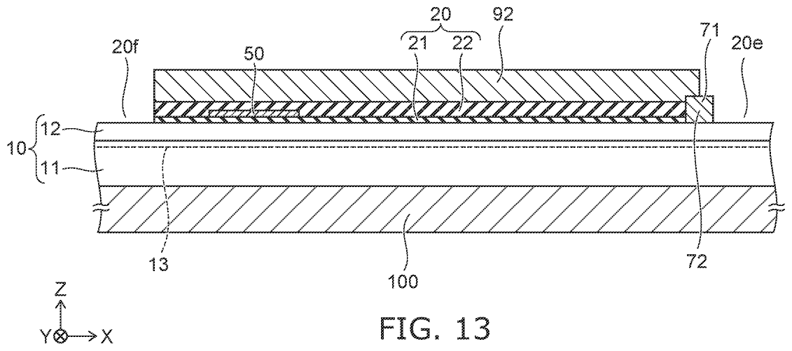

As shown in FIG. 13, the method for manufacturing the semiconductor device according to the first example of the third embodiment includes a process of forming a first opening 20e in the insulating film 20. For example, the first opening 20e can be formed by RIE using a mask 92. For example, a resist mask can be used as the mask 92. The first opening 20e is formed in a portion of the insulating film 20 next to the metal diffusion region 72. A second opening 20f can be formed in the insulating film 20 simultaneously with the first opening 20e. The nitride semiconductor layer 10 is exposed from under the insulating film 20 in the first and second openings 20e and 20f.

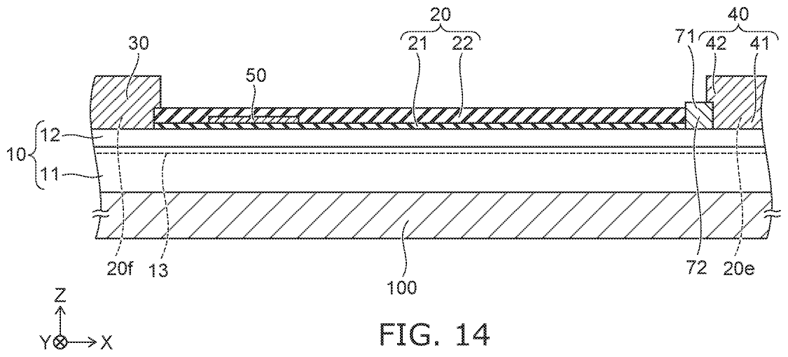

The mask 92 is removed after forming the first opening 20e and the second opening 20f. After removing the mask 92, the method for manufacturing the semiconductor device according to the first example of the third embodiment includes a process of forming the drain electrode 40 as shown in FIG. 14.

The drain electrode 40 includes the first part 41 that contacts the nitride semiconductor layer 10 in the first opening 20e, and the second part 42 that is positioned on the metal diffusion region 72. The first part 41 also contacts the side surface of the metal diffusion region 72. The metal film 71 remains on the metal diffusion region 72; and the second part 42 is positioned on the metal diffusion region 72 with the metal film 71 interposed. The metal diffusion region 72 and the metal film 71 correspond to the conductive part 70 of the semiconductor device 3 shown in FIG. 4.

The source electrode 30 can be formed simultaneously with the drain electrode 40. The source electrode 30 contacts the nitride semiconductor layer 10 in the second opening 20f.

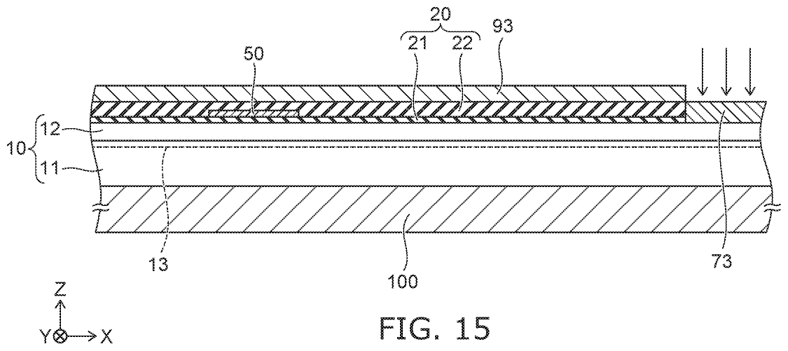

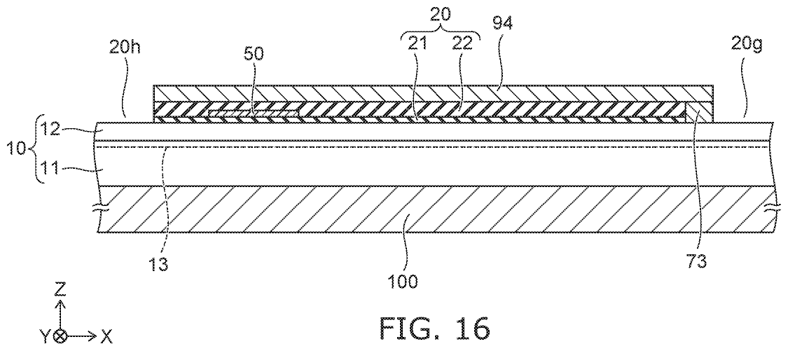

A method for manufacturing a semiconductor device according to a second example of the third embodiment will now be described with reference to FIGS. 15 and 16.

According to the method for manufacturing the semiconductor device according to the second example of the third embodiment, the processes up to the process of forming the insulating film 20 shown in FIG. 6 above are similar to those of the first embodiment.

Subsequently, the method for manufacturing the semiconductor device according to the second example of the third embodiment includes a process of forming a modified region 73 in a portion of the insulating film 20 as shown in FIG. 15. The process of forming the modified region 73 includes a process of forming a mask 93 on the insulating film 20 and a process of ion implantation into a portion of the insulating film 20 not covered with the mask 93. For example, a resist mask can be used as the mask 93. For example, Si or Ar are implanted into the portion of the insulating film 20 and cause crystal defects in the insulating film 20. The modified region 73 that is conductive is formed by the crystal defects in the insulating film 20.

As shown in FIG. 16, the method for manufacturing the semiconductor device according to the second example of the third embodiment includes a process of forming a first opening 20g to expose the nitride semiconductor layer 10 by removing a portion of the modified region 73.

For example, the first opening 20g can be formed by removing a portion of the modified region 73 not covered with a mask 94 by RIE using the mask 94. A second opening 20h also can be formed in the insulating film 20 simultaneously with the first opening 20g.

The mask 94 is removed after forming the first opening 20g and the second opening 20h. After the mask 94 is removed, the method for manufacturing the semiconductor device according to the second example of the third embodiment includes a process of forming the drain electrode 40. The source electrode 30 can be formed in the second opening 20h simultaneously with the formation of the drain electrode 40.

The drain electrode 40 includes the first part 41 that contacts the nitride semiconductor layer 10 in the first opening 20g, and the second part 42 that is positioned on the modified region 73. The first part 41 also contacts the side surface of the modified region 73. The modified region 73 corresponds to the conductive part 70 of the semiconductor device 3 shown in FIG. 4.

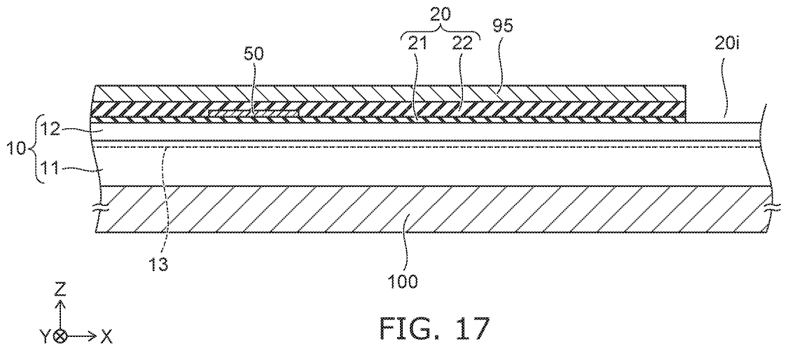

A method for manufacturing a semiconductor device according to a third example of the third embodiment will now be described with reference to FIGS. 17 to 20.

According to the method for manufacturing the semiconductor device according to the third example of the third embodiment, the processes up to the process of forming the insulating film 20 shown in FIG. 6 above are similar to those of the first embodiment.

Subsequently, the method for manufacturing the semiconductor device according to the third example of the third embodiment includes a process of forming a first opening 20i in a portion of the insulating film 20 to expose the nitride semiconductor layer 10 as shown in FIG. 17. For example, the first opening 20i can be formed by RIE using a mask 95. For example, a resist mask can be used as the mask 95.

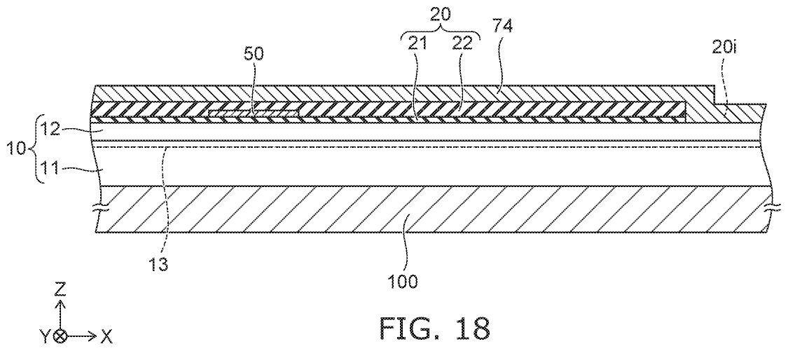

After forming the first opening 20i, the method for manufacturing the semiconductor device according to the third example of the third embodiment includes a process of forming a semi-insulating film 74 as shown in FIG. 18. The semi-insulating film 74 is formed continuously on the insulating film 20 and in the first opening 20i. For example, the semi-insulating film 74 can be formed by CVD.

The conductivity of the semi-insulating film 74 is greater than the conductivity of the insulating film 20. For example, a silicon nitride film can be used as the semi-insulating film 74. The nitrogen composition ratio in the silicon nitride film can be set to be not less than 40% and not more than 55%. Also, a SIPOS (Semi-Insulated Polycrystalline Silicon) film can be used as the semi-insulating film 74.

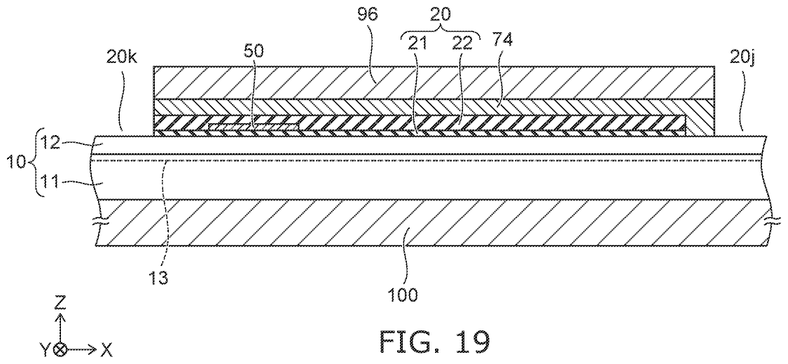

The method for manufacturing the semiconductor device according to the third example of the third embodiment includes a process of forming a second opening 20j by removing a portion of the semi-insulating film 74 formed in the first opening 20i. As shown in FIG. 19, the nitride semiconductor layer 10 is not covered with the semi-insulating film 74 and the insulating film 20 in the second opening 20j.

For example, the second opening 20j can be formed by RIE using a mask 96. For example, a resist mask can be used as the mask 96. A third opening 20k also can be formed in the insulating film 20 simultaneously with the second opening 20j.

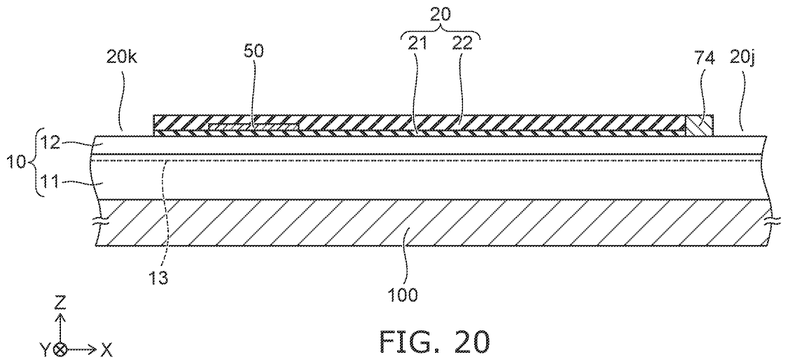

The mask 96 is removed after the second and third openings 20j and 20k are formed. The semi-insulating film 74 that is on the insulating film 20 is removed after the mask 96 is removed. As shown in FIG. 20, the semi-insulating film 74 remains at the portion next to the second opening 20j. For example, the semi-insulating film 74 on the insulating film 20 can be removed by CMP or etch-back.

The method for manufacturing the semiconductor device according to the third example of the third embodiment includes a process of forming the drain electrode 40 in the second opening 20j. The source electrode 30 can be formed in the third opening 20k simultaneously with the formation of the drain electrode 40.

The drain electrode 40 includes the first part 41 that contacts the nitride semiconductor layer 10 in the second opening 20j, and the second part 42 that is positioned on the semi-insulating film 74. The first part 41 also contacts the side surface of the semi-insulating film 74. The semi-insulating film 74 corresponds to the conductive part 70 of the semiconductor device 3 shown in FIG. 4.

The conductive part 70 of the semiconductor device 3 shown in FIG. 4 can be formed by forming a conductive film of tungsten, polycrystalline silicon doped with an impurity, or the like in the first opening 20i by the same process as the method for manufacturing the semiconductor device according to the third example of the third embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a nitride semiconductor layer including
a first layer, and
a second layer located on the first layer, the second layer having a wider bandgap than the first layer;
a source electrode located on the nitride semiconductor layer, the source electrode contacting the nitride semiconductor layer;
a drain electrode located on the nitride semiconductor layer, the drain electrode being positioned distant to the source electrode in a first direction, the drain electrode contacting the nitride semiconductor layer;
a gate electrode positioned between the source electrode and the drain electrode, the gate electrode not contacting the nitride semiconductor layer;
an insulating film located on the nitride semiconductor layer between the source electrode and the drain electrode; and
a conductor layer positioned between the gate electrode and the drain electrode, the conductor layer contacting the nitride semiconductor layer, the conductor layer being electrically connected with the drain electrode,
the drain electrode including
a first part contacting the nitride semiconductor layer, and
a second part positioned further toward the conductor layer side than the first part in the first direction,
the insulating film including a portion positioned between the conductor layer and the drain electrode,
the second part being located on the portion of the insulating film.

2. The device according to claim 1, further comprising:
a drain wiring part extending in the first direction,
the drain electrode and the conductor layer extending in a second direction,
the second direction crossing the first direction,
the drain electrode and the conductor layer being connected with the drain wiring part.

3. The device according to claim 1, wherein
the second part of the drain electrode contacts the conductor layer.

4. The device according to claim 1, wherein
a distance between the conductor layer and the first part of the drain electrode in the first direction is less than a distance between the gate electrode and the conductor layer in the first direction.

5. The device according to claim 1, wherein
the insulating film includes:
a first film located at a surface of the nitride semiconductor layer; and
a second film located on the first film,
the second film is thicker than the first film,
the gate electrode is located on the first film, and
the second film covers the gate electrode.

6. A semiconductor device, comprising:
a nitride semiconductor layer including
a first layer, and
a second layer located on the first layer, the second layer having a wider bandgap than the first layer;
a source electrode located on the nitride semiconductor layer, the source electrode contacting the nitride semiconductor layer;
a drain electrode located on the nitride semiconductor layer, the drain electrode being positioned distant to the source electrode in a first direction, the drain electrode contacting the nitride semiconductor layer;
a gate electrode positioned between the source electrode and the drain electrode, the gate electrode not contacting the nitride semiconductor layer;
an insulating film located on the nitride semiconductor layer and between the source electrode and the drain electrode; and
a conductive part positioned between the insulating film and the drain electrode, the conductive part contacting the drain electrode and the nitride semiconductor layer,
the insulating film not being positioned between the conductive part and the drain electrode,
the drain electrode including
a first part contacting the nitride semiconductor layer, and
a second part located on the conductive part.

7. The device according to claim 6, wherein
the conductive part is made of a material having a different composition from the drain electrode.

8. A method for manufacturing a semiconductor device, the method comprising:
preparing a nitride semiconductor layer, the nitride semiconductor layer including
a first layer, and
a second layer located on the first layer, the second layer having a wider bandgap than the first layer;
forming an insulating film on the nitride semiconductor layer;
forming a first opening in the insulating film to expose the nitride semiconductor layer;
forming a conductor layer in the first opening;
forming a second opening in the insulating film so that a portion of the insulating film remains between the conductor layer and the second opening, the second opening exposing the nitride semiconductor layer; and
forming the drain electrode,
the drain electrode including
a first part contacting the nitride semiconductor layer in the second opening, and
a second part positioned further toward the conductor layer side than the first part, the second part being positioned on the portion of the insulating film.

9. The method for manufacturing the device according to claim 8, wherein
the forming of the drain electrode includes causing the second part to contact the conductor layer.

10. A method for manufacturing a semiconductor device, the method comprising:
preparing a nitride semiconductor layer, the nitride semiconductor layer including
a first layer, and
a second layer located on the first layer, the second layer having a wider bandgap than the first layer;
forming an insulating film on the nitride semiconductor layer;
forming a metal film on the insulating film;
forming a metal diffusion region in the insulating film thermally diffusing a metal included in the metal film into the insulating film under the metal film;
forming a first opening in a portion of the insulating film next to the metal diffusion region, the first opening exposing the nitride semiconductor layer; and
forming a drain electrode, the drain electrode including
a first part contacting the nitride semiconductor layer and the metal diffusion region in the first opening, and
a second part positioned on the metal diffusion region.

11. A method for manufacturing a semiconductor device, the method comprising:
preparing a nitride semiconductor layer, the nitride semiconductor layer including
a first layer, and
a second layer located on the first layer, the second layer having a wider bandgap than the first layer;
forming an insulating film on the nitride semiconductor layer;
forming a modified region in a portion of the insulating film by ion implantation into the portion of the insulating film;
forming a first opening by removing a portion of the modified region, the first opening exposing the nitride semiconductor layer; and
forming a drain electrode,
the drain electrode including
a first part contacting the nitride semiconductor layer and the modified region in the first opening, and
a second part positioned on the modified region.

12. A method for manufacturing a semiconductor device, the method comprising:
preparing a nitride semiconductor layer, the nitride semiconductor layer including
a first layer, and
a second layer located on the first layer, the second layer having a wider bandgap than the first layer;
forming an insulating film on the nitride semiconductor layer;
forming a first opening in a portion of the insulating film to expose the nitride semiconductor layer;
forming a semi-insulating film in the first opening, the semi-insulating film having a higher conductivity than the insulating film;
forming a second opening by removing a portion of the semi-insulating film, the second opening exposing the nitride semiconductor layer; and
forming a drain electrode,
the drain electrode including
a first part contacting the nitride semiconductor layer and the semi-insulating film in the second opening, and
a second part positioned on the semi-insulating film.
